(19) United States
(12) Patent Application Publication
(10) Pub. No.: US 2026/0181840 A1
(43) Pub. Date: Jun. 25, 2026

(54) DATACENTER FAN REGULATION PROCESS

(71) Applicant: OVH, Roubaix (FR)

(72) Inventors: Ali CHEHADE, Moncheaux (FR); Mohamad HNAYNO, La Madeleine (FR); Hadrien BAUDUIN, Villeneuve d’Ascq (FR)

(21) Appl. No.: 19/419,622

(22) Filed: Dec. 15, 2025

(30) Foreign Application Priority Data
Dec. 20, 2024 (EP) 24307257.6

(51) Int. Cl. H05K 7/20

(52) U.S. Cl. CPC H05K 7/20836; H05K 7/20736; H05K 7/20781

(57) ABSTRACT

A method for controlling a speed of a fan of a dry cooling unit of a datacenter, the method comprising: estimating a thermal load (Q) of the rack-mounted data processing assemblies, estimating an air flow (AF) depending on the thermal load (Q) and an ambient temperature of the air flow (T_{amb}), estimating a fan rotation speed of said at least one fan assembly depending on the estimated air flow (AF), and controlling a voltage of said at least one fan assembly depending on the estimated fan rotation speed (nfan), wherein the process comprises a step of modeling the air flow (AF) as a polynomial function of the ambient temperature.

### CROSS-REFERENCE

The present patent application claims priority to European Patent Application Number 24307257.6 filed on Dec. 20, 2024, the disclosure of which is hereby incorporated by reference herein in its entirety.

### FIELD

The present technology generally relates to the field of datacenter liquid cooling arrangements.

### BACKGROUND

Datacenters as well as many computer processing facilities house multitudes rack-mounted electronic processing equipment. In operation, such electronic processing equipment generates a substantial amount of heat that must be dissipated in order avoid electronic component failures and ensure continued efficient processing operations.

To this end, various liquid cooling measures have been implemented to facilitate the dissipation of heat generated by the electronic processing equipment. One such measure employs liquid block cooling techniques for directly cooling one or more heat-generating processing components. This technique utilizes liquid cooling blocks having internal channels that receive cooling liquid from a cooling liquid source that are in thermal contact with the heat-generating processing components.

Depending on the access to water resources, in many cases, the preferred cooling liquid source comprises a dry cooling unit. Dry cooling units supply cooling liquid via pumps to rack-mounted electronic processing equipment as well as receive heated liquid from the electronic processing equipment and are configured to re-cool the received heated liquid for circulation back to the electronic processing equipment.

The energy consumption of datacenters is a significant issue due to several factors. Datacenters require a substantial amount of electricity to power servers and storage devices. This demand is growing rapidly, driven by an increasing use of cloud computing, big data analytics and artificial intelligence, for instance. Also, the cooling systems themselves consume a large amount of energy. The high energy consumption of datacenters contributes to greenhouse gas emissions, which have a significant impact on climate change.

Efforts to improve energy efficiency are crucial to mitigate these effects.

As such, there remains an interest in attempting to minimize the energy consumption of the cooling systems of datacenters.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches.

### SUMMARY

Embodiments of the present technology have been developed based on certain drawbacks associated with conventional dry cooling techniques and implementations to improve energy efficiency.

In one aspect of the inventive concepts, the present technology relates to a liquid cooling method for a datacenter liquid cooling system for cooling rack-mounted processing assemblies, the datacenter liquid cooling system comprising a cooling arrangement provided with:
a cooling unit configured to supply a cooling liquid to the rack-mounted processing assemblies and receive a heated liquid from the rack-mounted processing assemblies,
a forward liquid distribution circuit including a temperature sensor, and/or a forward valve to convey the cooling liquid from the cooling unit to the rack-mounted processing assemblies,
a return liquid distribution circuit including a temperature sensor and/or a valve to convey the heated liquid from the rack-mounted processing assemblies back to the cooling unit and,
a control module panel communicatively-coupled to the temperature sensor, temperature sensor, to receive data therefrom,
each of the rack-mounted data processing assemblies comprising at least one heat-generating electronic processing element and at least one liquid cooling block arranged to be in respective thermal contact with the at least one heat-generating electronic processing element and fluidly-coupled to the first forward liquid distribution circuit,
the cooling unit comprising at least one fan assembly and at least one heat exchanger assembly for cooling the liquid circulating in the system and entering the cooling unit by the return liquid distribution circuit by a flow of air,
   the method comprises a step of
estimating a thermal load (Q) of the rack-mounted data processing assemblies,
estimating an air flow (AF) depending on the thermal load (Q) and an ambient temperature of the air flow (T_{amb}),
estimating a fan rotation speed of said at least one fan assembly depending on the estimated air flow (AF), and
controlling a voltage of said at least one fan assembly depending on the estimated fan rotation speed (nfan),
wherein the process comprises a step of modeling the air flow (AF) as a polynomial function of the ambient temperature.

The fan controlling method of the present technology ensures energy consumption reduction as well as better water cooling.

In some embodiments, the polynomial function is a six-degree polynomial:

$$A F ( Δ T , Q , T ) = {a}_{6} {T}_{a m b}^{6} + {a}_{5} {T}_{a m b}^{5} + {a}_{4} {T}_{a m b}^{4} + {a}_{3} {T}_{a m b}^{3} + {a}_{2} {T}_{a m b}^{2} + {a}_{1} {T}_{a m b} + {a}_{0}$$

In some embodiments, coefficient a₆ is comprised between 10⁻⁶ and 5*10⁻⁴ m³/(h° C.⁶).

In some embodiments, coefficient a₅ is comprised between 10⁻⁵ and 6*10⁻³ m³/(h° C.⁵).

In some embodiments, coefficient a₄ is comprised between −2*10⁻³ and 2*10⁻² m³/(h° C.⁴).

In some embodiments, coefficient a₃ is comprised between −5*10⁻¹ and 0.5 m³/(h° C.³).

In some embodiments, coefficient a₂ is comprised between 1 and 50 m³/(h° C.²).

In some embodiments, coefficient a₁ is advantageously comprised between 1 and 600 m³/(h° C.).

In some embodiments, coefficient do is advantageously comprised between 1000 and 30000 m³/h.

In some embodiments, the method comprises a step of modeling the rotation speed of the fan of the at least one fan assembly as a second-degree polynomial of the air flow.

In some embodiments, the method comprises a step of comparing an electrical power calculated with the estimated fan speed and a real electrical power of the fan of the at least one fan assembly.

In some embodiments, the method comprises a step of sampling the estimated thermal load (Q).

In some embodiments, the method comprises a step of sampling the difference of temperature between a temperature of the liquid entering the cooling unit and a temperature of the liquid exiting the cooling unit.

The present technology also relates to a system configured to implement the method as already described.

The present technology also relates to a computer program comprising instructions which, when the program is executed by a computer, cause the computer to carry out the steps of the method as already described.

The present technology also relates to a computer-readable medium comprising instructions which, when executed by a computer, cause the computer to carry out the steps of the method as already described.

In the context of the present specification, unless expressly provided otherwise, a computer system may refer, but is not limited to, an “electronic device”, an “operation system”, a “system”, a “computer-based system”, a “controller unit”, a “monitoring device”, a “control device” and/or any combination thereof appropriate to the relevant task at hand.

In the context of the present specification, unless expressly provided otherwise, the expression “computer-readable medium” and “memory” are intended to include media of any nature and kind whatsoever, non-limiting examples of which include RAM, ROM, disks (CD-ROMs, DVDs, floppy disks, hard disk drives, etc.), USB keys, flash memory cards, solid state-drives, and tape drives. Still in the context of the present specification, “a” computer-readable medium and “the” computer-readable medium should not be construed as being the same computer-readable medium. To the contrary, and whenever appropriate, “a” computer-readable medium and “the” computer-readable medium may also be construed as a first computer-readable medium and a second computer-readable medium.

In the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 illustrates a high-level functional block diagram of a datacenter liquid cooling system comprising a liquid arrangement, in accordance with the nonlimiting embodiments of the present technology;

FIG. 2 illustrates a flow diagram of a fan regulation process of fans of the system of FIG. 1, in accordance with the nonlimiting embodiments of the present technology; and

FIG. 3 illustrates a high-level functional block diagram of a controller for the liquid cooling system of FIG. 1.

It should be appreciated that, unless otherwise explicitly specified herein, the drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes that may be substantially represented in non-transitory computer-readable media and so executed by a computer or processor, whether or not such computer or processor is explicitly shown.

The functions of the various elements shown in the FIGs. including any functional block labeled as a “processor”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. In some embodiments of the present technology, the processor may be a general-purpose processor, such as a central processing unit (CPU) or a processor dedicated to a specific purpose, such as a digital signal processor (DSP). Moreover, explicit use of the term a “processor” should not be construed to refer exclusively to hardware capable of executing software, and may implicitly include, without limitation, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown. Moreover, it should be understood that module may include for example, but without being limitative, computer program logic, computer program instructions, software, stack, firmware, hardware circuitry or a combination thereof which provides the required capabilities.

Equally noteworthy, while various operations of the inventive concepts may be represented by flowchart elements arranged in certain sequential order, it should be understood that these steps may be combined, sub-divided, re-ordered, or changed to operate concurrently without departing from the teachings of the present technology. In fact, at least some of the processing steps may be executed in parallel or in series. Accordingly, the ordering, sequencing, and grouping of the processing steps is not a limitation of the present technology.

Given this fundamental understanding, the disclosed embodiments are directed to a system and method configured to minimize the damaging effects due to crucial flow component failures of a single liquid cooling arrangement by sharing liquid cooling components/resources of other liquid cooling arrangements.

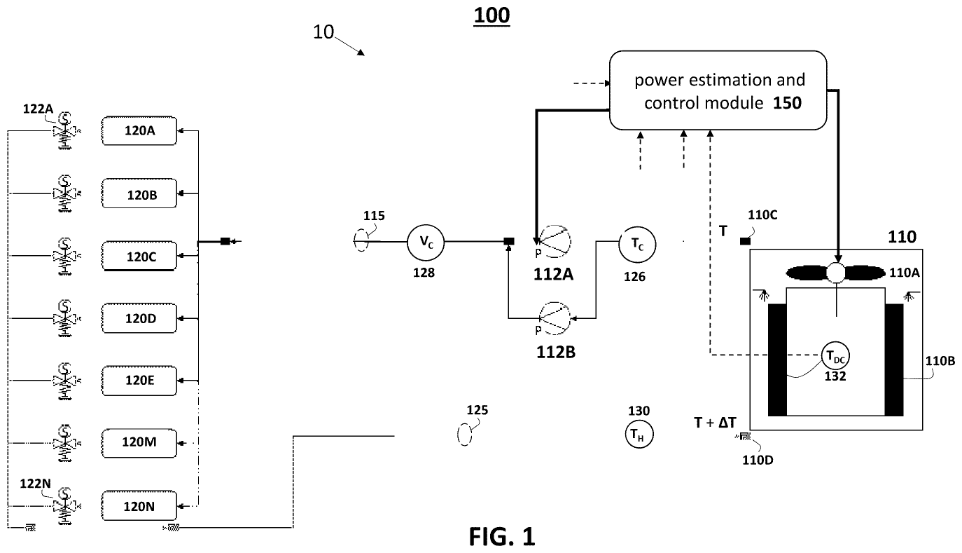

FIG. 1 illustrates a high-level functional block diagram of a datacenter liquid cooling system 10 comprising a liquid cooling arrangement 100 for cooling corresponding rack-mounted processing assemblies, in accordance with the nonlimiting embodiments of the present technology.

As shown, the liquid cooling arrangement 100 of system 10 includes a dry cooling unit 110, a plurality of rack-mounted processing assemblies 120A-120N, a plurality of smart valves 122A-122N in which each smart valve is fluidly-coupled to a respective processing assembly, a forward liquid distribution circuit 115 incorporating at least one pump 112A for supplying cooling liquid from the dry cooling unit 110 (two pumps on 112A, 112B on FIG. 1), a return liquid distribution circuit 125 for returning heated liquid back to the dry cooling unit 110 and, optionally, a control module panel 150 communicatively coupled to various components and sensors.

The dry cooling unit 110 may be located on any suitable stable support surface, such as, for example, the roof of a datacenter/computer processing facility building. The dry cooling unit 110 serves to dissipate thermal energy from a heated liquid circulating therethrough to the ambient environment. For example, in a datacenter or similar facility, the dry cooling unit 110 operates to receive heated liquid from the respective rack-mounted processing assemblies 120A-120N and extracts the thermal energy from the heated liquid by dissipating the energy into the ambient environment via the respective at least one fan assembly 110A to thereby re-cool the heated liquid. The dry cooling unit 110 then operates to supply the re-cooled liquid back to the respective rack-mounted processing assemblies 120A-120N.

As shown, the dry cooling unit 110 includes at least one heat exchanger 110B and at least one fan assembly 110A. The heat exchanger 110B may manifest a variety of configurations, such as, air-to-liquid heat exchanger etc., a chiller, or cooling tower or a plate heat exchange, and may further include evaporative cooling pads. For purposes of the instant disclosure, the exact configuration of the dry cooling unit 110 and heat exchanger 110B is not limiting, as various configurations could be employed without departing from the concepts of the instant disclosure.

As also shown, the forward liquid distribution circuit 115 incorporates at least one pump 112A.

Optionally, the forward liquid distribution circuit 115 also incorporates a forward “smart” control valve 119A. For purposes of the instant disclosure, the term “smart” valve refers to a valve that is pressure-independent, temperature-responsive, incorporates a differential pressure regulator to automatically adjust to system pressure changes as well as shut down given certain operational conditions. Such smart valves may comprise PICVs, ABQMs, other functionally similar valves, or combinations of valves, such as a solenoid valve combined with a control valve. In this implementation, the smart control valve 119A is configured to sense and adjust the flow of the cooling/re-cooled liquid supplied to the processing assemblies 120A-120N. Advantageously, the forward smart control valves 119A are also communicatively coupled to the control module panel to provide notification about the liquid flow.

The heated liquid from the rack-mounted processing assemblies 120A-120N is returned back to the dry cooling unit 110 for re-cooling via the respective return liquid distribution circuit 125.

As depicted, the dry cooling unit 110 supplies the cooling/re-cooled liquid to the rack-mounted processing assemblies 120A-120N at a nominal temperature T and the heated liquid returned to the dry cooling unit 110 is at a nominal temperature T+ΔT, where ΔT represents the temperature differential between the cooling/re-cooled liquid and the heated liquid.

The liquid cooling arrangement 100 of system 10 includes a plurality of rack-mounted processing assemblies 120A-120N which receive the supplied cooling/re-cooled liquid via the corresponding forward liquid distribution circuit 115 to internally channel the cooling liquid to the heat-generating processing components (e.g., water circulated through water blocks), and convey the heated liquid from the heat-generating processing components to the return liquid distribution circuit 125.

The rack-mounted processing assemblies 120A-120N may or may not be configured with similar heat-generating processing components. As such, each of the rack-mounted processing assemblies 120A-120N may have different temperature and flow rate requirements for proper operations.

It will be appreciated that, while the rack-mounted processing assemblies 120A-120N are depicted to be arranged in a parallel configuration, it is not meant to be limiting, as the processing assemblies 120A-120N may also be arranged in a serial or combined parallel and serial configuration without departing from the concepts of the instant disclosure.

Each of the rack-mounted processing assemblies 120A-120N can be fluidly-coupled to a smart valve 122A-122N that dynamically controls the flow rate of the corresponding processing assembly 120A-120N based on detected liquid temperatures.

Along the forward liquid distribution circuit 115, liquid cooling arrangement 100 also incorporates temperature sensor 126 for measuring the temperature of the supplied cooling liquid T_{C}, flow pressure sensor 127 for measuring the pressure of the flow of the supplied liquid P, and a volume sensor 128 for measuring the flow rate of the supplied cooling liquid V_{C}.

For the return liquid distribution circuit 125, liquid cooling arrangement 100 also incorporates temperature sensor 125 for measuring the temperature of the return heated liquid T_{H}.

As will be described in detail below, another parameter of interest are the “pinch” values of the heat exchanger assembly 110B. That is, each heat exchanger assembly 110B has a “hot side” and a “cold side”. For the hot side, the pinch value ΔThotpinch is defined as the difference between the temperature of the hot air exiting the heat exchanger and the temperature of the hot liquid entering the heat exchanger. And, for the cold side, the pinch value ΔTcoldpinch is defined as the difference between the temperature of the fresh air entering the heat exchanger and the temperature of cold liquid exiting the heat exchanger. Both of the pinch values ΔThotpinch, ΔTcoldpinch are positive numbers. The pinch value of the cold side is noted Pinch from now on.

Each of the measured T_{C}, V_{C}, T_{H}, and T_{DC} (T_{DC}=T_{amb} after the cooling pad, if there is) values are then supplied to the control panel 150. As will be described in detail below, based on these measured values, module 150 functions to determine the estimated power consumed by the rack-mounted processing assemblies 120A-120N and dynamically controls a rotational speed of dry cooling unit fan assembly 110A to improve cooling system efficiency.

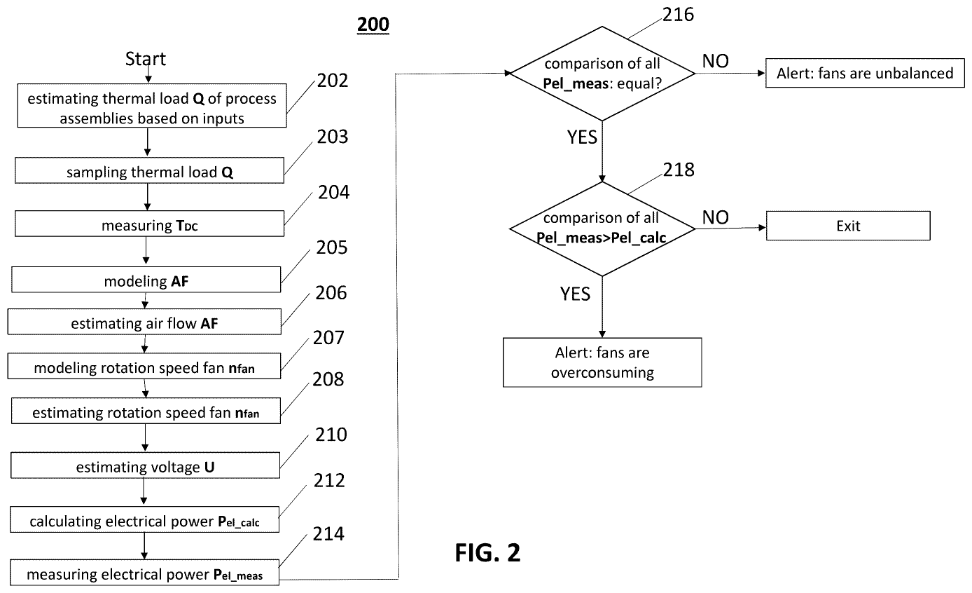

With this said, FIG. 2 illustrates a flow diagram of fan control process 200 of a liquid cooling system for rack-mounted processing assemblies, in accordance with the non-limiting embodiments of the present technology. The power estimation and fan control process 200 may be executed by control module 150. The execution of module 150 may be performed by a controller 600.

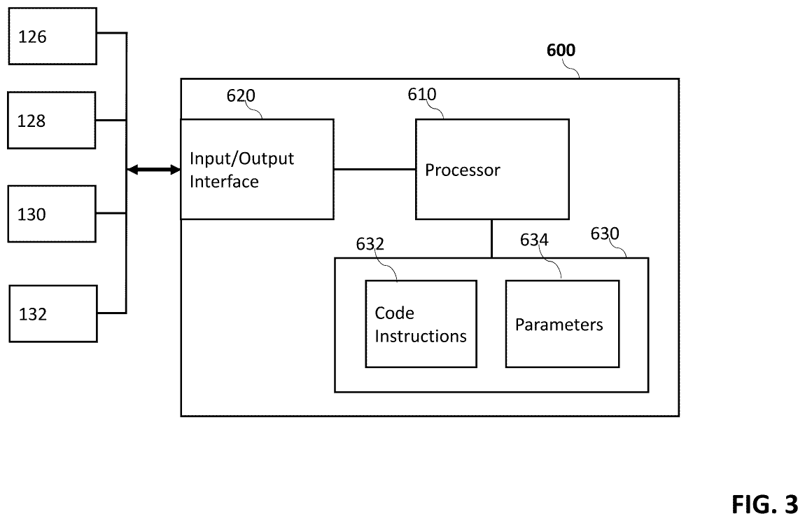

For example, such a controller is depicted by the high-level functional block diagram of FIG. 3. As shown, the controller 600 comprises a processor or a plurality of cooperating processors (represented as a processor 610 for simplicity), a memory device or a plurality of memory devices (represented as a memory device 630 for simplicity), and an input/output interface 620 (or separate input and output interfaces) allowing the controller 600 to communicate with certain components of the liquid cooling arrangement 100. The processor 610 is operatively connected to the memory device 630 and to the input/output interface 620. The memory device 630 includes a storage for storing parameters 634, including for example and without limitation the above-mentioned pre-determined conductivity thresholds. The memory device 630 may comprise a non-transitory computer-readable medium for storing code instructions 632 that are executable by the processor 610 to allow the controller 600 to perform the various tasks allocated to the controller 600.

The controller 600 is operatively connected, via the input/output interface 620, to the components of liquid cooling arrangement 100, such as, the temperature sensor 126 that measures the temperature of cooling liquid T_{C}, the temperature sensor 132 that measures the temperature of ambient dry cooling unit temperature T_{DC}, the temperature sensor 130 that measures the temperature of heated liquid T_{H}, and the volume sensor 128 that measures the cooling liquid flow rate V_{C}, The controller 600 executes the code instructions 632 stored in the memory device 630 to implement the various above-described functions of the control module 150.

However, it will be appreciated that in other embodiments, power estimation and fan control process 200 or portions thereof may be executed by relevant components, such as, for example, temperature sensors, volume sensors, and pumps, etc. For purposes of the instant disclosure, the exact entity or entities executing process 200 is not limiting with regard to the inventive concepts herein presented.

Returning back to FIG. 2, process 200 commences at step 202, in which the thermal load Q of the forward liquid distribution circuit 115 is estimated. The thermal load Q of the forward liquid distribution circuit 115 corresponds to the power consumed by the rack-mounted processing assemblies 120A-120N. As such, process 200 determines ΔT representative of the temperature differential between the supplied cooling liquid temperature, as measured by T_{C}, and the returning heated liquid temperature, as measured by T_{H}. Process 200 then computes the estimated thermal load Q of the forward liquid distribution circuit 115 based on the relationship: thermal load Q=m·cp·ΔT, where m represents the mass flow rate of water and cp represents the specific heat calculated as a function of the fluid average temperature.

In some embodiments, process 200 then moves to step 203 to discretizing the estimated thermal load Q by sampling the thermal load Q on subsequent regular ranges, the sampled thermal load being the maximal value on each range. For instance, the load ranks can increase each 50 kW, from 50 kW to 800 kW. In this case, if the estimated thermal load is 425 kW, the sampled estimated thermal load is 450 kW. Alternatively, the load ranks can increase each 25 kW.

In some embodiments, the method also comprises a step of sampling the difference ΔT.

Process 200 then moves to step 204 to evaluate the measured ambient temperature of the dry cooling unit 110 T_{DC}, which depends on whether evaporative cooling pads are employed. Advantageously, the ambient temperature is considered to be comprised between-30° C. and 22° C.

Then, as will be detailed, process 200 evaluates the dry cooling unit fan assembly 110A operating parameters. Such operating parameters may include, but are not limited to, fan speed n_{fan} (in rotations per minute: rpm), fan piloting voltage U (approximately between 0-10V), fan efficiency parameter η (in %), and estimated fan power consumption P_{elec_calc}. It will be appreciated that these operating parameters may be influenced by prevailing conditions, such as, for example, thermal load Q, ambient dry cooling unit temperature T_{DC}, outdoor humidity, and other factors, like altitude.

At step 206, the air flow AF is determined by the values of the ambient temperature, the ΔT and the sampled thermal load Q. Process 200 advantageously comprises a preliminary step 205 of expressing the air flow as a polynomial function of the ambient temperature. The coefficients of each power of ambient temperature depends at least on the ΔT and the sampled thermal load.

For instance, the air flow is a 6-degree polynomial of the ambient temperature:

$$A F ( Δ T , Q , T ) = {a}_{6} {T}_{a m b}^{6} + {a}_{5} {T}_{a m b}^{5} + {a}_{4} {T}_{a m b}^{4} + {a}_{3} {T}_{a m b}^{3} + {a}_{2} {T}_{a m b}^{2} + {a}_{1} {T}_{a m b} + {a}_{0} .$$

where all the coefficients aₙ are computed based on the set of values (ΔT,Q).

Coefficient a₆ is advantageously comprised between 10⁻⁶ and 5*10⁻⁴ m³/(h° C.⁶), for instance comprised between 10⁻⁵ and 5*10⁻⁵ m³/(h° C.⁶).

Coefficient a₅ is advantageously comprised between 10⁻⁵ and 6*10⁻³ m³/(h° C.⁵), for instance comprised between 10⁻⁵ and 10⁻³ m³/(h° C.⁵).

Coefficient a₄ is advantageously comprised between −2*10⁻³ and 2*10⁻² m³/(h° C.⁴), for instance comprised between 10⁻³ and 10⁻² m³/(h° C.⁴).

Coefficient a₃ is advantageously comprised between −5*10⁻¹ and 0.5 m³/(h° C.³).

Coefficient a₂ is advantageously comprised between 1 and 50 m³/(h° C.²), for instance comprised between 1 and 20 m³/(h° C.²).

Coefficient a₁ is advantageously comprised between 1 and 600 m³/(h° C.), for instance comprised between 50 and 550 m³/(h° C.).

The coefficient do is advantageously comprised between 1000 and 30000 m³/h, for instance comprised between 4000 and 25000 m³/h.

Then, at step 208, process 200 evaluates the fan speed n_{fan} (in rotations per minute: rpm) depending on the air flow AF and the configuration of the fan.

Advantageously, process 200 comprises a preliminary step 207 of determining the fan speed as a function of the air flow AF for the configuration of the fan, that depends on the pressure drop in the dry cooling unit, and particularly on the pressure drop induced by the specific heat exchanger assembly 110B of the dry cooling unit, as well as on the efficiency parameter η.

For instance, per each heat exchanger, the fan speed fan is a 2-degree polynomial of the air flow AF:

$${n}_{fan} = {b}_{2} A {F}^{2} + {b}_{1} A F + {b}_{0}$$

The fan speed n_{fan} is comprised between 0 and 1000 RPM, for instance between 0 and 980 RPM.

The fan speed n_{fan} is comprised between 0 and nₘₐₓ, for instance between 0 and 980 RPM.

Coefficient b₂ is advantageously comprised between 10⁻¹¹ and 10⁻⁹ RPM·(h/m³)².

Coefficient b₁ is advantageously comprised between 10⁻⁵ and 10⁻³ RPM·h/m³.

Coefficient b₀ is advantageously comprised between 10⁻¹ and 10² RPM.

Parameter η is comprised between 0 and 100%.

Process 200 comprises a step 210 of calculating the voltage to be applied to the fan. The voltage U is proportional to the fan speed n_{fan}. For instance, U is chosen to be comprised between 0V and 10V, such that it can be expressed as:

$$U = \frac{{n}_{fan}}{{n}_{max}} * 10$$

The maximal fan speed nₘₐₓ can be 1000 RPM.

Then, at step 212, an electrical power Pel_calc is calculated as a function of the fan speed n_{fan}.

At step 214, process 200 comprises measuring the real electrical power Pel_meas of the fan assembly 110A. If the system 10 comprises more than one fan, at step 216, process 200 checks if all the fans have an electrical power that are equal with a given tolerance (+10% for instance, or +20% for instance). If they do not, process 200 issues an alert that the fans are unbalanced or overconsuming. If they do, then, at step 218, there is a comparison between the calculated electrical power Pel_calc and the measured electrical power Pel_meas. If the measured electrical power Pel_meas is lower than the calculated electrical power, process 200 exits. If the measured electrical power is higher than the calculated electrical power, an alert is issued that the fans are overconsuming.

Process 200 is advantageously repeated at a regular frequency, each 30 minutes for example, each 3 minutes for example, or could be an average of a laps of time.

An example is now given, with a thermal load estimated at step 202 to 366 kW and ΔT=18K. At step 203 the estimated thermal load Q is sampled to 375 kW, considering increase ranks of 25 kW. At step 206, the air flow is determined by the values of the ambient temperature, the temperature differential ΔT and the sampled thermal load Q, as is shown in FIG. 3. In this example, the air flow is a 6-degree polynomial of the ambient temperature:

$$A F ( Δ T , Q , T ) = {a}_{6} {T}_{a m b}^{6} + {a}_{5} {T}_{a m b}^{5} + {a}_{4} {T}_{a m b}^{4} + {a}_{3} {T}_{a m b}^{3} + {a}_{2} {T}_{a m b}^{2} + {a}_{1} {T}_{a m b}^{1} + {a}_{0} ,$$

where all the coefficients aₙ are computed based on the set of values (ΔT,Q).

Advantageously, coefficients an come from the complete design and characterization process, as all the thermal and operating points of the dry cooling unit 110 have been predicted and/or measured, feeding a database, the sampling step easing the way to link the operation with the model and find the right coefficients each time process 200 is executed and query the database.

The ambient temperature being measured at 21° C. gives an air flow value of AF(18, 300, 21)=41968 m³/h. Then, at step 208, process 200 evaluates the fan speed n_{fan} (in rotations per minute: rpm) depending on the air flow AF and the configuration of the fan, with a static pressure increase of 78.11 Pa and an efficiency parameter η of 71.4%. The fan speed is estimated to n_{fan}=762 RPM and a voltage of 7.8V. The associated electrical power Pel_calc equals 1003.3 W.

Process 200 comprises a sub-process 400 of anticipating the evolution of the voltage control.

Sub-process 400 aims at smoothing the voltage U that is being applied to the fan assembly 110A instead of working either to 0V or a maximal value, like, for instance, 9V or 10V.

Sub-process 400 comprises a step 402 of determining an air temperature, called triggering temperature, or actuation temperature, such that the voltage triggers on the triggering temperature before the set temperature Ti and a voltage minimum is to be communicated with the fans at the triggering temperature. The triggering temperature of T_{C}, referenced to as Ti-min, can be expressed as

$${T}_{i - min} = {T}_{i} - M ,$$

where M is a margin.

At step 404, sub-process 400 comprises determining the set point Ti depending on the ambient temperature T_{amb} and the sampled thermal load Q.

Advantageously, the set point of T_{C} is chosen as follows:
If the ambient temperature is lower than or equal to a threshold temperature, for instance 22° C., and the sampled thermal load Q is lower than or equal to a threshold thermal load, for example 500 kW, then the set point is a lower set point T_{iL}, for example 25° C.,

This configuration takes advantage of the cold ambient air that can cool quite easily the liquid entering the dry cooling since the thermal load is rather low;
If the ambient temperature is lower than or equal to a threshold temperature, for instance 22° C., and the sampled thermal load Q is higher than the threshold thermal load, for example 500 kW, then the set point is a higher set point T_{iH}, for example 27° C.,

This configuration takes advantage of the cold ambient air but the thermal load being higher (compared to the previously described configuration), the set point is chosen higher;
If the ambient temperature is higher than the threshold temperature, for instance 22° C., and the sampled thermal load Q is lower than or equal to the threshold thermal load, for example 500 kW, then the set point is chosen as

$${T}_{i} = {T}_{a m b} + {P}_{i n c h}^{L} , where {P}_{i n c h}^{L}$$

is for instance of 3K,

This configuration takes into account the not so fresh air and the low thermal load;
If the ambient temperature is higher than the threshold temperature, for instance 22° C., and the sampled thermal load Q is higher than the threshold thermal load, for example 500 kW, then the set point is chosen as

$${T}_{i} = {T}_{a m b} + {P}_{i n c h}^{H} , where {P}_{i n c h}^{H}$$

is for instance of 5K;

This configuration takes into account the not so fresh air and the high thermal load.

In some embodiments, the margin M is a constant. In some embodiments, the margin M is function of Uₘₐₓ (in percentage). For instance, M is a linear function of Uₘₐₓ. For instance, M=c*Uₘₐₓ+d, where c and d are coefficients.

The margin M is a value to calculate the set point for fans kick ON; so it is in ° C.

Coefficient c can depend on the amplitude of the fan voltage and coefficient d can depend on coefficient c. For example

$$c = \frac{{V}_{max} - {V}_{min}}{{A}_{\% max} - {A}_{\% max}} ,$$

and d=Vₘₐₓ−c*A_{% max},
where A_{% max} is the maximal percentage of the voltage that can be applied to the fans and A_{% min} is the minimal percentage of the voltage that can be applied to the fans. For instance, Vₘᵢₙ is comprised between 0V and 2V, Vₘₐₓ is comprised between 9 and 10V, A_{% min} is comprised between 5 and 15% and A_{% max} is comprised between 90 and 100%.

While the above-described implementations have been described and shown with reference to particular steps performed in a particular order, it will be understood that these steps may be combined, sub-divided, or re-ordered without departing from the teachings of the present technology. At least some of the steps may be executed in parallel or in series. Accordingly, the order and grouping of the steps is not a limitation of the present technology.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A liquid cooling method for a datacenter liquid cooling system for cooling rack-mounted processing assemblies, the datacenter liquid cooling system comprising a cooling arrangement provided with:
a cooling unit configured to supply a cooling liquid to the rack-mounted processing assemblies and receive a heated liquid from the rack-mounted processing assemblies,
a forward liquid distribution circuit including a temperature sensor, to convey the cooling liquid from the cooling unit to the rack-mounted processing assemblies,
a return liquid distribution circuit a temperature sensor to convey the heated liquid from the rack-mounted processing assemblies back to the cooling unit,
a controller \ communicatively-coupled to the temperature sensor, temperature sensor, to receive data therefrom,
each of the rack-mounted data processing assemblies comprising at least one heat-generating electronic processing element and at least one liquid cooling block arranged to be in respective thermal contact with the at least one heat-generating electronic processing element and fluidly-coupled to the forward liquid distribution circuit,
the cooling unit comprising at least one fan assembly and at least one heat exchanger assembly for cooling the liquid circulating in the system and entering the cooling unit by the return liquid distribution circuit by a flow of air,
the method comprises a step of
estimating a thermal load (Q) of the rack-mounted data processing assemblies,
estimating an air flow (AF) depending on the thermal load (Q) and an ambient temperature of the air flow (T_{amb}),
estimating a fan rotation speed of said at least one fan assembly depending on the estimated air flow (AF), and
controlling a voltage of said at least one fan assembly depending on the estimated fan rotation speed (nfan),
wherein the process comprises a step of modeling the air flow (AF) as a polynomial function of the ambient temperature.

2. The method of claim 1, wherein the polynomial function is a six-degree polynomial:
$$A F ( Δ T , Q , T ) = {a}_{6} {T}_{a m b}^{6} + {a}_{5} {T}_{a m b}^{5} + {a}_{4} {T}_{a m b}^{4} + {a}_{3} {T}_{a m b}^{3} + {a}_{2} {T}_{a m b}^{2} + {a}_{1} {T}_{a m b} + {a}_{0} .$$

3. The method of the claim 2, wherein coefficient a₆ is comprised between 10⁻⁶ and 5*10⁻⁴ m³/(h° C.⁶).

4. The method of claim 2, wherein coefficient a₅ is comprised between 10⁻⁵ and 6*10⁻³ m³/(h° C.⁵).

5. The method of claim 2, wherein coefficient a₄ is comprised between −2*10⁻³ and 2*10⁻² m³/(h° C.⁴).

6. The method of claim 2, wherein coefficient a₃ is comprised between −5*10⁻¹ and 0.5 m³/(h° C.³).

7. The method of claim 2, wherein coefficient a₂ is comprised between 1 and 50 m³/(h° C.²).

8. The method of claim 2, wherein coefficient a₁ is advantageously comprised between 1 and 600 m³/(h° C.).

9. The method of claim 2, wherein coefficient a₀ is advantageously comprised between 1000 and 30000 m³/h.

10. The method of claim 1, comprising a step of modeling the rotation speed of the fan of the at least one fan assembly as a second-degree polynomial of the air flow.

11. The method of claim 1, comprising a step of comparing an electrical power calculated with the estimated fan speed and a real electrical power of the fan of the at least one fan assembly.

12. The method of claim 1, comprising a step of sampling the estimated thermal load (Q).

13. The method of claim 1, comprising a step of sampling a difference of temperature between a temperature of the liquid entering the cooling unit and a temperature of the liquid exiting the cooling unit.

14. A datacenter liquid cooling system for cooling rack-mounted processing assemblies, the datacenter liquid cooling system comprising a cooling arrangement provided with:
a cooling unit configured to supply a cooling liquid to the rack-mounted processing assemblies and receive a heated liquid from the rack-mounted processing assemblies,
a forward liquid distribution circuit including a temperature sensor, to convey the cooling liquid from the cooling unit to the rack-mounted processing assemblies,
a return liquid distribution circuit a temperature sensor to convey the heated liquid from the rack-mounted processing assemblies back to the cooling unit,
a controller communicatively-coupled to the temperature sensor, temperature sensor, to receive data therefrom,
each of the rack-mounted data processing assemblies comprising at least one heat-generating electronic processing element and at least one liquid cooling block arranged to be in respective thermal contact with the at least one heat-generating electronic processing element and fluidly-coupled to the forward liquid distribution circuit,
the cooling unit comprising at least one fan assembly and at least one heat exchanger assembly for cooling the liquid circulating in the system and entering the cooling unit by the return liquid distribution circuit by a flow of air,
a processor configured to:
estimate a thermal load (Q) of the rack-mounted data processing assemblies,
estimate an air flow (AF) depending on the thermal load (Q) and an ambient temperature of the air flow (T_{amb}),
estimate a fan rotation speed of said at least one fan assembly depending on the estimated air flow (AF), and
estimate a voltage of said at least one fan assembly depending on the estimated fan rotation speed (nfan),
wherein the process comprises a step \ of modeling the air flow (AF) as a polynomial function of the ambient temperature.

15. The system of claim 14, wherein the polynomial function is a six-degree polynomial:
$$A F ( Δ T , Q , T ) = {a}_{6} {T}_{a m b}^{6} + {a}_{5} {T}_{a m b}^{5} + {a}_{4} {T}_{a m b}^{4} + {a}_{3} {T}_{a m b}^{3} + {a}_{2} {T}_{a m b}^{2} + {a}_{1} {T}_{a m b} + {a}_{0} .$$

16. The system of the claim 15, wherein coefficient a₆ is comprised between 10⁻⁶ and 5*10⁻⁴ m³/(h° C.⁶).

17. The system of the claim 15, wherein coefficient a₅ is comprised between 10⁻⁵ and 6*10⁻³ m³/(h° C.⁵).

18. The system of the claim 15, wherein coefficient a₄ is comprised between −2*10⁻³ and 2*10⁻² m³/(h° C.⁴).

19. The system of the claim 15, wherein coefficient a₃ is comprised between −5*10⁻¹ and 0.5 m³/(h° C.³).

20. A liquid cooling method for a datacenter liquid cooling system for cooling rack-mounted processing assemblies, the method comprising:
estimating a thermal load (Q) of the rack-mounted data processing assemblies,
estimating an air flow (AF) depending on the thermal load (Q) and an ambient temperature of the air flow (T_{amb}),
estimating a fan rotation speed of at least one fan assembly of a cooling unit configured to supply a cooling liquid to the rack-mounted processing assemblies, depending on the estimated air flow (AF), and
controlling a voltage of said at least one fan assembly depending on the estimated fan rotation speed (nfan),
wherein the process comprises a step of modeling the air flow (AF) as a polynomial function of the ambient temperature.
